(19) United States
(12) Patent Application Publication
(10) Pub. No.: US 2006/0180890 A1
(43) Pub. Date: Aug. 17, 2006

(54) Top emission flat panel display with sensor feedback stabilization

(76) Inventors: W. Edward Naugler JR., Cedar Park, TX (US); Damoder Reddy, Los Gatos, CA (US); Gordon Jun Liu, Fremont, CA (US)

Correspondence Address: HOWREY LLP, C/O IP DOCKETING DEPARTMENT, 2941 FAIRVIEW PARK DRIVE, SUITE 200, FALLS CHURCH, VA, 22042-2924, US

(21) Appl. No.: 11/335,043

(22) Filed: Jan. 18, 2006

Related U.S. Application Data
(60) Provisional application No. 60/645,521, filed on Jan. 18, 2005.

(51) Int. Cl. H01L 31/00

(52) U.S. Cl. 257/444

(57) ABSTRACT

The present invention discloses novel top emitter pixel circuitry for flat panel displays. Sensor material is deposited above a substrate. A pixilated opaque cathode is deposited above the sensor material. Organic light emitting diode material is deposited above the cathode. A transparent anode is deposited above the OLED material. Some of the layers have dielectric layers between them. The light emitted by the OLED material passes upwards through the transparent anode but cannot pass downwards through the opaque cathode. A deep via optically connects the OLED material layer with the sensor material layer. A transparent cathode can be used instead of the opaque cathode, thereby allowing the light generated by the OLED material layer to pass both upward through the transparent anode and downward through the transparent cathode. That would eliminate the need for a deep via to form an optical path between the OLED material layer and the sensor layer. However, that would require the addition of a shield to shield the active matrix circuitry from the light generated by the OLED material layer.

### RELATED APPLICATION

The present application claims priority to U.S. Provisional Patent Application No. 60/645,521, filed on Jan. 18^{th}, 2005.

### FIELD OF INVENTION

The present invention relates to flat panel displays.

### BACKGROUND OF THE INVENTION

A new emissive type flat panel display technology called organic light emitting diode (OLED) is in the process of development by many companies around the world such as Sharp, Toshiba, Samsung, and many more. The primary technical problems with the commercialization of the OLED display are manufacturing uniformity and differential color aging over the lifetime of the display. These problems have been addressed by several provisional and formal patent applications assigned to the Nuelight Corporation. Refer to U.S. patent application Ser. No. 10/872,344 entitled Method and Apparatus for Controlling an Active Matrix Display and U.S. patent application Ser. No. 10/872,268 entitled Controlled Passive Display Apparatus and Method for Controlling and making a passive display. These patent applications show how to use an emission feedback system to solve the problems of OLED uniformity and differential aging in analog driven display systems.

In previous patent applications filed by Nuelight Corporation, the type of emission system for the active matrix flat panel is termed by the industry as a down emitter. In the down emitter display, the active matrix and sensor circuitry is first deposited and patterned on a transparent (glass or plastic) substrate. On top of the active matrix circuit the OLED or emissive structure is deposited. The opaque cathode of the OLED is the last layer to be deposited; therefore, light emitted by the OLED could not pass through the cathode to a viewer. This meant that the light reflected off the inside surface of the cathode and exited down through the transparent substrate.

Because the active matrix circuitry is sensitive to the emitted light, it has to be shielded from the light emitted by the OLED. As a result, the OLED material has to be restricted to clear areas of the pixel not occupied by active matrix circuitry. This causes the emissive area of the pixel to be only a fraction of the pixel area. If only a fraction of the pixel area emits light, then the brightness of the OLED must be increased to make up for the area of the pixel that does not emit light. The area of the pixel that is emissive is called the pixel's aperture. In many OLED down emitter flat panel displays, the active matrix circuitry takes up as much as 80 percent of the pixel area. Therefore, the OLED material must emit light at lease five times brighter than for which the pixel is designed.

Recent display developments have introduced the up emitter emissive display. These displays are able to use as much as 80 to 90 percent of the pixel's area, because the active matrix circuitry can be tucked underneath the emitting OLED material. In order to produce an up emitter, either a transparent cathode must be used or the opaque cathode must be placed under the emitting portion of the OLED. This disclosure shows how to use both a transparent cathode as a top layer or an opaque layer under the OLED emitter.

### SUMMARY OF THE INVENTION

The present invention discloses novel top emitter pixel circuitry for flat panel displays. Sensor material is deposited above a substrate. A pixilated opaque cathode is deposited above the sensor material. Organic light emitting diode material is deposited above the cathode. A transparent anode is deposited above the OLED material. Some of the layers have dielectric layers between them. The light emitted by the OLED material passes upwards through the transparent anode but cannot pass downwards through the opaque cathode. A deep via optically connects the OLED material layer with the sensor material layer. A transparent cathode can be used instead of the opaque cathode, thereby allowing the light generated by the OLED material layer to pass both upward through the transparent anode and downward through the transparent cathode. That would eliminate the need for a deep via to form an optical path between the OLED material layer and the sensor layer. However, that would require the addition of a shield to shield the active matrix circuitry from the light generated by the OLED material layer.

### BRIEF DESCRIPTION OF THE DRAWINGS

The above and other objects and advantages of the present invention will be apparent upon consideration of the following detailed description, taken in conjunction with the accompanying drawings, in which like reference characters refer to like parts throughout, and in which:

FIG. 1 shows an exemplary device of the present invention that includes an opaque pixilated cathode and deep vias to align edge emission of the OLED with the edge of the sensor;

FIG. 2 shows an exemplary five mask manufacturing process for fabricating the devices of the present invention;

FIG. 3 shows another exemplary device of the present invention that includes two transparent electrodes and an un-biased sensor;

FIG. 4 shows another exemplary device of the present invention that includes two transparent electrodes, a bottom TFT gate, a biased sensor and a Faraday shield;

FIG. 5 shows another exemplary device of the present invention that includes an opaque pixilated cathode, shallow vias, a non-aligned OLED edge emission, and a biased sensor;

FIG. 6 shows another exemplary device of the present invention that includes an opaque pixilated cathode, shallow vias, a non-aligned OLED edge emission, and an un-biased sensor;

FIG. 7 shows another exemplary device of the present invention that includes an opaque pixilated cathode and an optical sensor in the form of a reverse biased OLED;

FIG. 8 shows an exemplary schematic of the device of FIG. 7 illustrating the layers of the forward biased emitting OLED and the reverse biased sensor OLED;

FIG. 9 shows an exemplary schematic of the pixel circuitry of the present invention that uses the reverse biased OLED sensor; and

FIG. 10 shows an exemplary schematic of the pixel circuitry of the present invention that used the channel semiconductor sensor.

### DETAILED DESCRIPTION OF THE INVENTION

The present invention covers top emitter pixel circuitry and methods for fabricating same. The top emitter pixel circuitry of the present invention can also be referred to as the up emitter pixel circuitry. The active matrix circuitry included in the top emitter pixel circuitry of the present invention is located under the OLED emitter that has either a pixilated cathode (negative electrode) structure with a transparent anode layer (positive electrode) for the emitting surface, or has a transparent cathode as the emitting surface. In one embodiment, the cathode is opaque and pixilated. In that embodiment, a deep via is used to align the edge of the OLED emitter with the edge of the sensor.

In another embodiment, both electrodes (anode and cathode) are transparent and thus interchangeable. In that embodiment, the metal gate of the thin film transistor (TFT) of the active matrix is a top gate that is situated between the emitting OLED and the TFT channel, to shield the TFT channel from the light emitted by the OLED. The sensor does not have shielding and is exposed directly to the OLED emission. Also, there is no sensor bias electrode in this embodiment to manage the conductivity of the sensor.

In another embodiment, the metal gate is a bottom gate. A portion of the bottom gate material on the same layer is also used as a bias electrode for the sensor. The bias electrode is thus situated below the sensor and therefore does not reduce the light emission of the OLED that strikes the sensor. An opaque Faraday shield is employed between the bottom electrode of the OLED (cathode) and the channel of the TFT so that the voltage on the OLED does not influence the channel of the TFT. An opening in the Faraday shield over the sensor allows scattered light from the OLED emission to strike the sensor.

In another embodiment, the basic structure used in the first embodiment above is used but the opening in the opaque cathode is not aligned with the sensor by using a deep via, and scattering in the adjacent transparent dielectric layers is relied upon to deliver OLED light emission to the sensor located under a dark bias electrode. In another embodiment, the same structure as the first embodiment above is used except the sensor does not have a bias electrode. In another embodiment, the semiconductor material used for the sensor is replaced with a reverse biased OLED, and the sensor is isolated from the emission OLED.

There are many other embodiments of this invention that involve the full range of OLED materials from the Kodak small molecule material to the polymer OLEDs and phosphorescent OLEDs. The active matrix may use any type of semiconductor material including amorphous silicon, poly silicon, or monolithic silicon, or cadmium selenide to name a few.

In order to produce the devices of the present invention, various techniques well known in the semiconductor industry are used including: material deposition processes including but not limited to evaporation; sputtering and plasma enhanced chemical vapor deposition; etching processes including but not limited to wet chemical etching; reactive ion etching and sputter etching; and photolithographic processes.

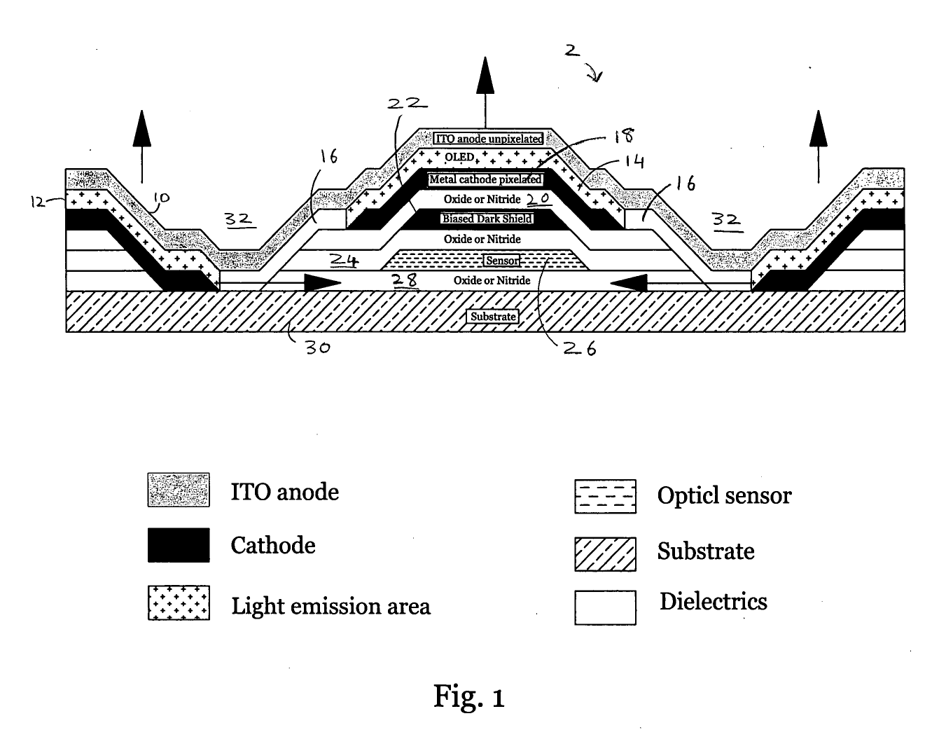

Referring to FIG. 1, a cross section of the sensor portion of an exemplary pixel circuit 2 of the present invention is shown. The light gray layer 10 is the top layer and is a continuous anode (positive electrode) for the OLED. Layer 10 can be made from a conductive transparent material such as Indian Tin Oxide (ITO). The arrows at the top of layer 10 are pointing in the upward direction indicating the upward direction of the light emitted by the top emitter device of FIG. 1. Under the anode layer 10 is the OLED emitter layer 12. FIG. 1 does not show details of the details of layer 12, which includes the electron transport layer (ETL), the hole transport layer (HTL) and the recombination layer where electron hole recombination causes light to be emitted).

The area of the OLED emitter layer 12 with the crosses 14 is where light is produced and no light is produced in the clear areas 16 because the black cathode layer 18 under the emitting layer 12 is interrupted to allow the passage of light to the sensor. The layer directly under the black cathode layer 18 is a clear layer of a dielectric 20 that can be any dielectric including but not limited to silicon dioxide, silicon nitride, or any other dielectric or combination of dielectrics. Under the clear dielectric layer 20 is the black biased dark shield or electrode 22. The purpose of the bias electrode 22 is to modify the conductivity of the sensor layer 26 to fine tune the sensor circuit. Under the bias electrode 22 is another dielectric layer 24 to insulate the sensor 26 from the bias electrode 22.

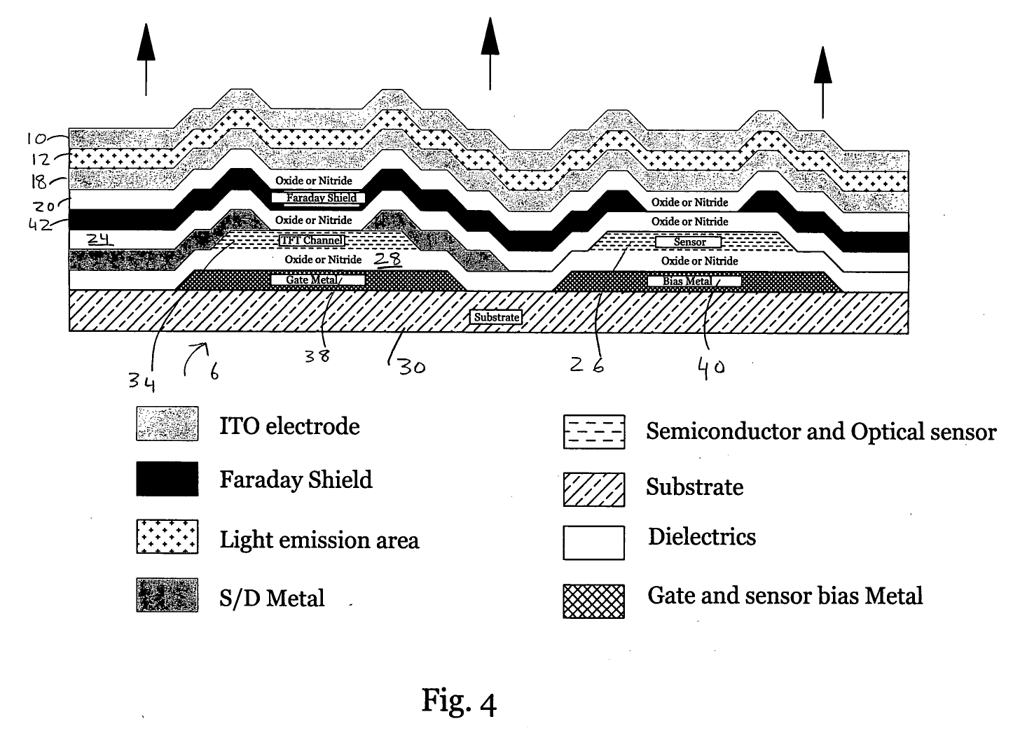

FIG. 1 does not show the thin film transistors (TFTs) used in the active matrix. Also, because the TFTs are not shown, the contact metal layers are not shown (refer to FIG. 4 for the contact metal structure). Under the dielectric layer 24 is the sensor structure 26 shown in dashed lines. The sensor material is the same semiconductor material used for the active matrix TFTs and is disposited on the substrate at the same time as the TFT semiconductors; therefore, the including of the sensor 26 adds no expense to the manufacturing process. Under the sensor structure 26 is a third clear dielectric layer 28 similar to the other two dielectric layers 20 and 24. The purpose of this dielectric layer 28 is to prevent any contaminants from the substrate material (shown with slanted hatching) 30 diffusing into the sensor 26 or TFT channel material.

According to FIG. 1, the deep vias 32 are used to align the edges of the OLED layer 12 and the sensor layer 26. The vias 32 can also be referred to as the depression layers. The deep vias 32 allow the sensor to detect the light emitted by the OLED 12. The two arrows in layer 28, with one arrowhead pointing right and the other arrowhead pointing left, show that the light generated by the OLED layer 12 reaches the sensor 26 by way of the transparent dielectric material of layer 28.

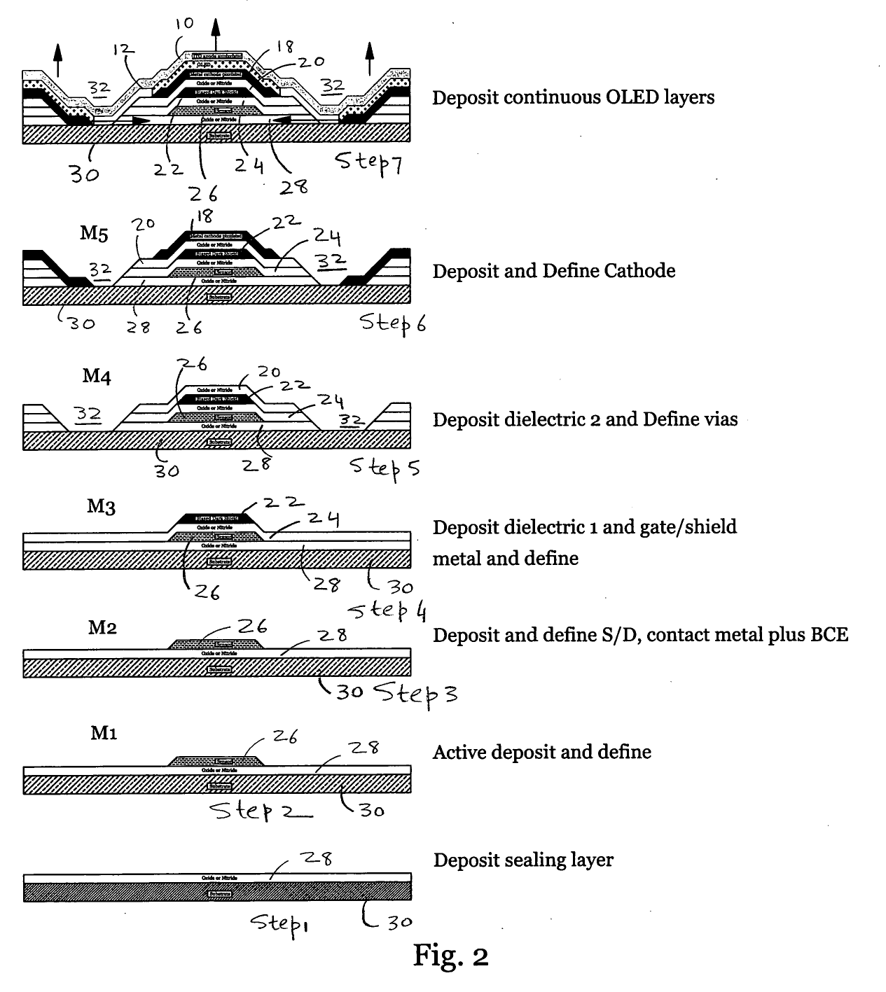

FIG. 2 shows the step by step process for the manufacture of the device of FIG. 1. This five mask process is only an example of a semiconductor process to achieve the structure of FIG. 1. There are other processes and procedure well known in the industry to produce this structure. The steps are shown from the bottom of the figure (Step 1) to the top of the figure (Step 7). The steps with the M designation require photolithographic masks. Only the steps to produce the active matrix and the sensor are shown. The steps to produce the OLED layers are not shown.

In Step 1, the substrate 30, which can be glass, plastic, metal or any other material that can hold the proper dimensions through the semiconductor process and stand up to the temperature and processes may be used, has a sealing and protection layer 28 deposited by any suitable deposition process used in the semiconductor industry. This layer 28 is unstructured and requires no masking step.

In Step 2, the active semiconductor layer 26 is deposited using a suitable deposition process including sputtering and plasma enhanced chemical vapor deposition (PECVD). The gas make-up and concentrations of hydrogen, helium and silane are typically provided in the literature for this process. This layer is structured using mask M1 into TFT channel elements and the sensor element with photolithographic processes well known in the industry. One type of process is known as the back channel etch (BCE) process, which starts with a two layer deposition of the normal TFT channel semiconductor followed by a highly phosphorus doped layer (n+ layer) which forms the interface material between the source/drain contact metal and the channel semiconductor material.

In Step 3, the source/drain (S/D) and sensor contact metal is deposited using well known processes in the industry. FIG. 2 does not show the S/D or sensor contact layer in order for simplicity. In Step three, after the metal pattern is structured using mask M2, the n+ layer shorting out the Source and Drain contacts is etched away down to the TFT channel semiconductor. This is a popular method of producing TFTs well known in the industry.

In Step 4, the Gate dielectric material 24 is deposited followed by the Gate metal and sensor bias electrode 22, which is structured using mask M3. In Step 5, the third dielectric 20 is deposited in similar fashion to the first two dielectrics 24 and 28. Also in Step 5, using mask M4, the vias 32 are cut in the dielectric 20, 24 and 28 to provide inter layer contacts and to lower the emission edge of the OLED material 14 to line up with the edge of the sensor element 26.

In Step 6, the cathode electrode 18 is deposited and structured to produce a pixilated cathode so that individual pixels can be addressed and controlled as is well known in the industry. In Step 7, the OLED material layer 12 including the ETL, recombination layer, HTL and the top transparent electrode 10 are deposited.

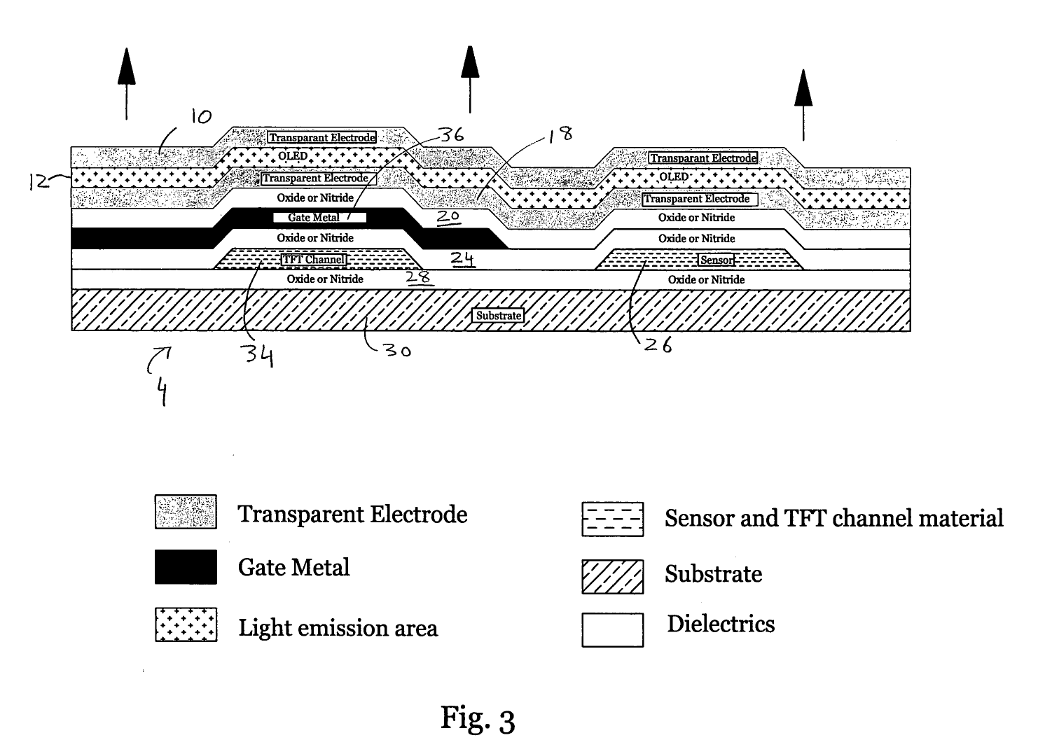

Referring to FIG. 3, the pixel circuit 4 shown there can also be fabricated by using the semiconductor process shown in FIG. 2, with some modifications. In the embodiment of FIG. 1, the cathode 18 was opaque forcing the use of edge emission to be used to illuminate the sensor 26. In the embodiment of FIG. 3, the electrode layers 10 (anode) and 18 (cathode) are transparent and thus there is no need to use a deep via to line up the emission layer 12 with the sensor layer 26. The gate metal 36 shields the TFT channel 34 from the emitted light from the OLED 12. The sensor element 26 has no bias shield and thus is fully exposed to both the emitted OLED light and the ambient light.

This means that steps must be taken to isolate the sensor data caused by the OLED emission from data caused by the ambient light. One way to do this is to take a dark frame data reading, which will give sensor data for the ambient light exposure with no OLED emission present. Then when the OLED emission data is taken the data contributed by the ambient light is subtracted out. This is a well known technique used in the astronomy industry for deep space photography.

Referring to FIG. 4, the pixel circuitry 6 shown there includes a bottom gate 38 for the TFT 34 and to provide a bias electrode 40 for the sensor element 26. To fabricate the device of FIG. 4, the process of FIG. 2 is modified to include the deposition of the gate metal 38 and the bias electrode 40. This can be done either before or after the sealing layer 28 is disposed on the substrate 30, depending on the requirements of the process. In one embodiment, after the gate metal deposition 38, the gate dielectric 28 is deposited followed by the TFT and sensor semiconductor material 34 and 26. Since the gate 38 is on the bottom, the TFT channel 34 is exposed to the OLED 12, the ambient light emission, and the electric field on the bottom OLED electrode 18.

Therefore, to protect the TFT channel 34 from OLED light emission and the OLED electric field, an opaque metallic layer is deposited called a Faraday shield 42. The Faraday shield 42 has an opening cut into it to allow OLED light emission to pass through to the sensor 36 below. The same data isolation techniques employed in the embodiment of FIG. 3 must be used for this embodiment.

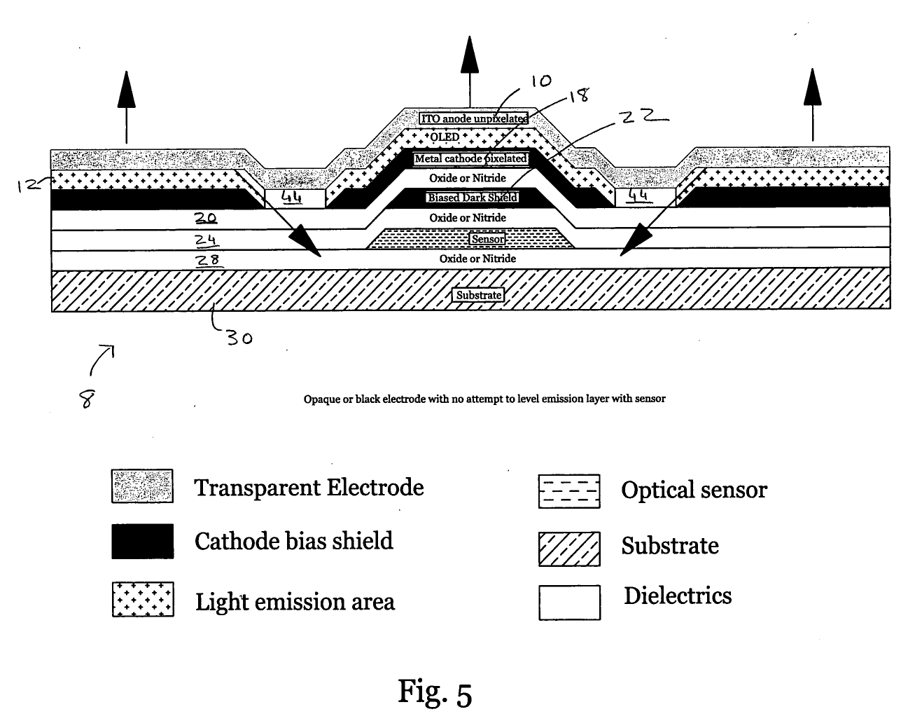

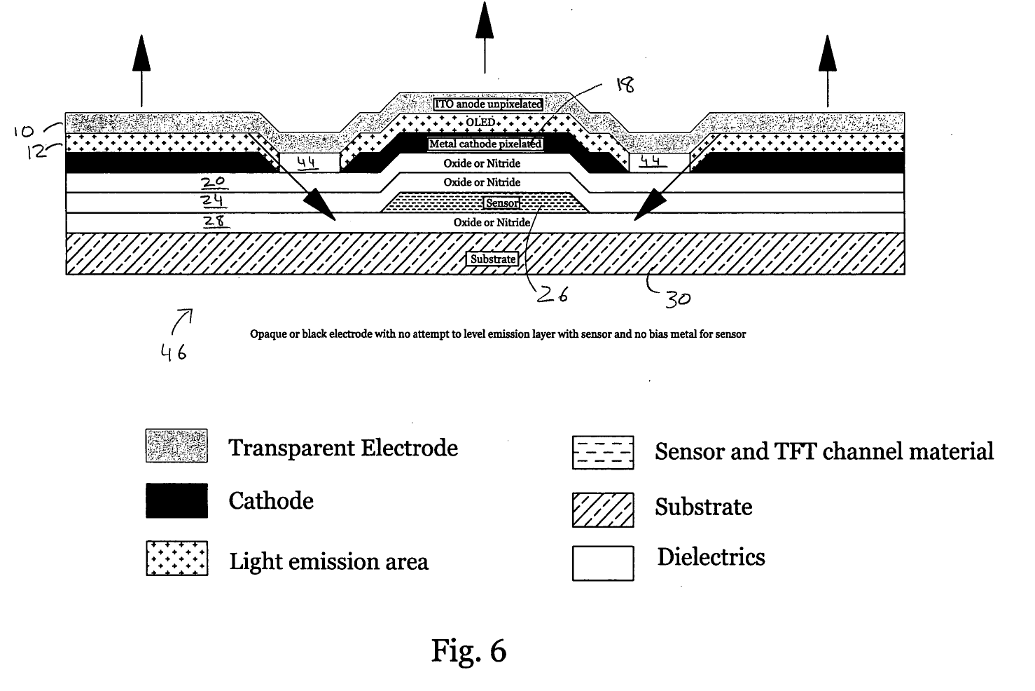

Referring to FIG. 5, in this embodiment of the pixel circuitry 8, the same basic structure and processes as used as in the embodiment of FIG. 1 are used, except that no deep vias 32 are cut down to the substrate 30, but only holes 44 in the opaque OLED cathode 18 are cut and light scattered down through the transparent dielectric layers 20, 24 and 28 is relied upon to expose the sensor 26. Referring to FIG. 6, in this embodiment of the pixel circuitry 46, the bias electrode 22 for the sensor 26, shown in FIG. 5, is excluded. Otherwise, this embodiment is identical to the FIG. 5 embodiment.

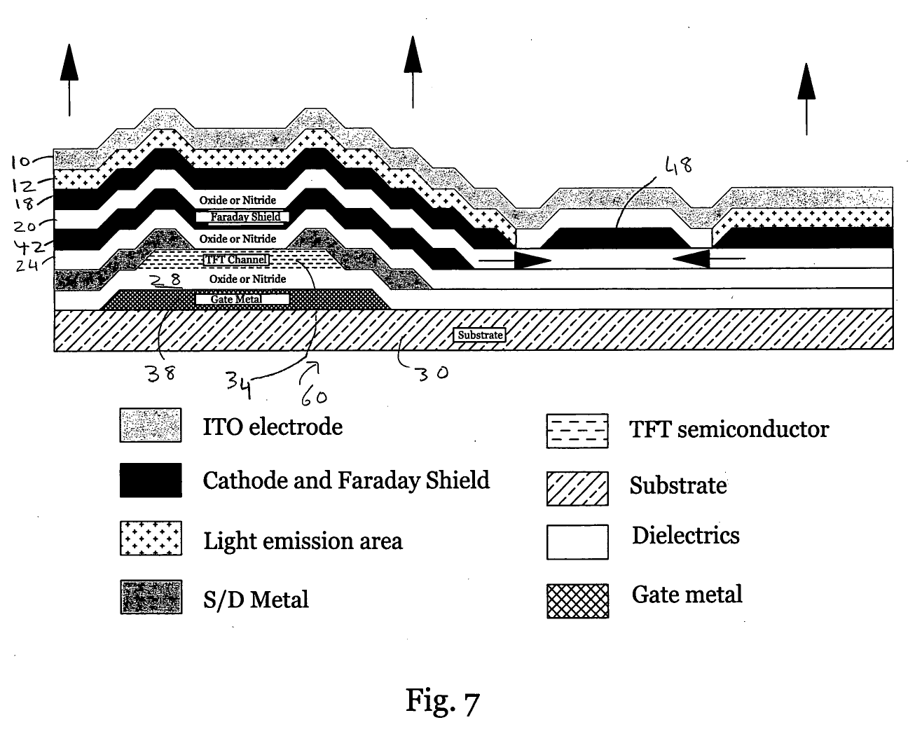

In the above embodiments, the sensor 26 was constructed of the same semiconductor material as were the TFT channels 34. In this embodiment of the pixel circuitry 60 shown in FIG. 7, the sensor 48 is formed using the OLED materials used for the pixel light emission layer 12. The OLED is a diode and emits light as do all light emitting diodes when it is biased in the forward direction. An OLED is forward biased when the anode of the OLED has a positive voltage with respect to the cathode of the OLED. If, however, the anode of the OLED has a voltage that is negative with respect to the cathode, the OLED is reversed biased and very little current is passed and no light is emitted.

The reverse current (leakage) in the reverse biased OLED is increased when light enters the space charge region of the diode. The larger the space charge region the more light in converted to reverse current. This fact can be used to advantage in making an optical sensor in the pixel. The requirement is that one electrode of the sensor diode be isolated from the emission diode. FIG. 7 show one structure among many that can be used. FIG. 7 shows a bottom gate 38 with Faraday shield 42. The embodiment of FIG. 7 can also function without the Faraday shield 42. The opaque cathode layer 18 is broken to provide a separately addressed electrode 48 for the reversed biased OLED used for the sensor.

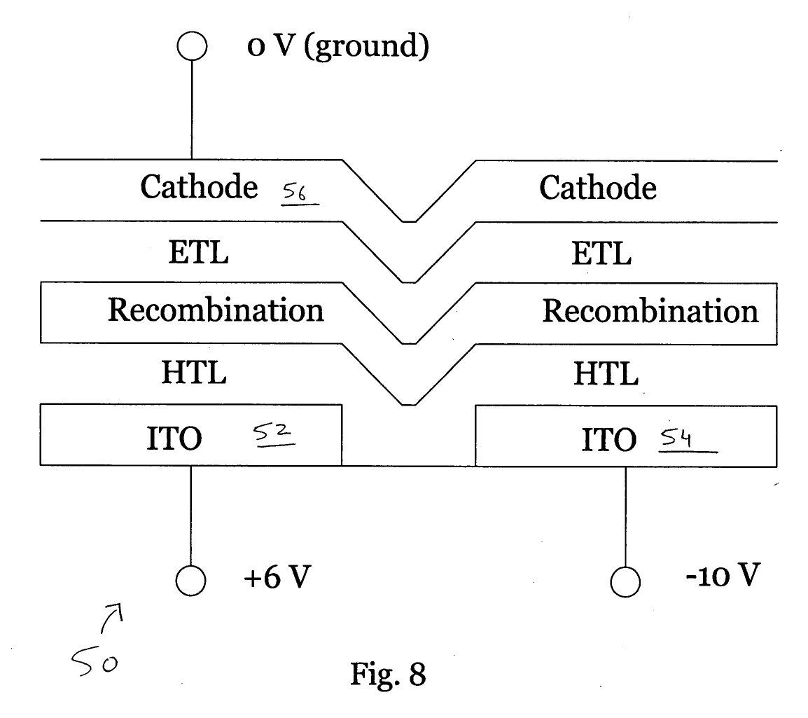

FIG. 8 shows the details for the pixel circuitry 50 having forward biased OLED emitter and the reverse biased OLED sensor. In this embodiment, the ITO anode layer is broken between the forward biased emitter OLED 52 and the reverse biased sensor OLED 54. All the other layers are continuous. This embodiment takes advantage of the fact that there is no lateral current flow in the OLED layers which are actually dielectrics until charge carriers are introduced by the hole-injecting anode and the electron-injecting cathode. In the embodiment shown in FIG. 8, the cathode 56 is continuous and is biased to be ground (0 V) while the ITO anode of the light emission section 52 of the OLED structure has a +6 volts applied to it and the anode of the sensor section 54 of the OLED has −10 volts applied to it. These voltages are only examples and various other voltages can be applied as long as the polarity of the electrode is preserved.

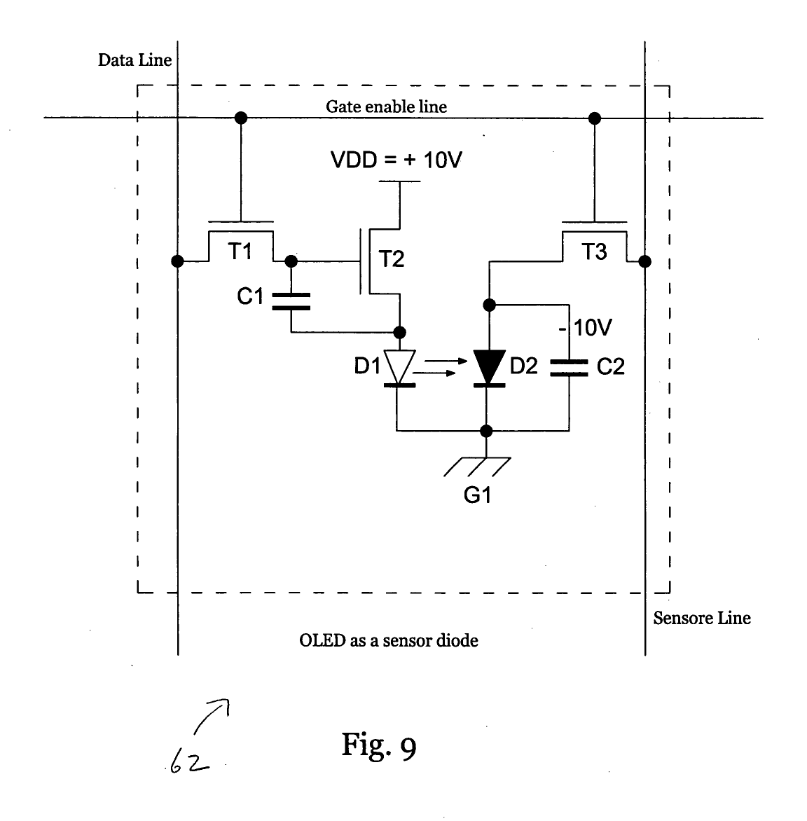

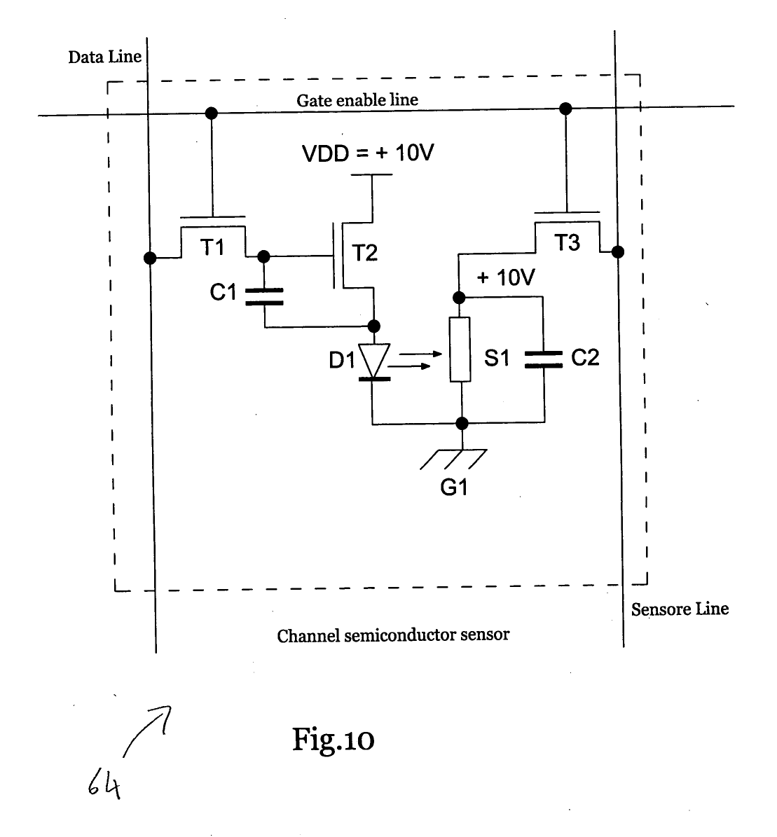

FIG. 9 show a pixel circuitry 62 schematic that uses the OLED D2 for a sensor diode and FIG. 10 shows the pixel circuitry 64 schematic that uses TFT channel sensor material S1 for a sensor diode. The only difference between the sensors of FIG. 9 and FIG. 10 is the polarity of the sensors, which in the case of the OLED sensor D2 is negative and in the case of the TFT channel semiconductor S1 is positive. The polarity of S1 could also be negative depending on the requirements of the drive system.

1. A semiconductor circuit for an emissive pixel comprising:
a substrate;
a sensor material layer above the substrate;
an opaque cathode material layer above the sensor material layer;
a light emission material layer above the opaque cathode material layer;
a transparent anode material layer above the light emission material layer; and
a transparent deep via for optically connecting the light emission material layer with the sensor emission material layer; wherein,
the light emitted by the light emission material layer passes through the transparent anode material layer; and
the light emitted by the light emission material does not pass through the opaque cathode material layer.

2. The semiconductor circuit of claim 1, wherein the light emission material of the light emission material layer includes an organic light emitting diode material.

3. The semiconductor circuit of claim 1, wherein the sensor material of the sensor material layer includes an organic light emitting diode material.

4. The semiconductor circuit of claim 3, wherein an organic light emitting diode of the sensor material layer is reverse biased during operation.

5. The semiconductor circuit of claim 1, further comprising:
a transparent dielectric material layer between the transparent deep via and the sensor material layer.

6. A semiconductor circuit for an emissive pixel comprising:
a substrate;
a sensor material layer above the substrate;
a transparent cathode material layer above the sensor material layer;
a light emission material layer above the transparent cathode material layer; and
a transparent anode material layer above the light emission material layer; wherein,
the light emitted by the light emission material layer passes through the transparent anode material layer and the transparent cathode material layer.

7. The semiconductor circuit of claim 6, wherein light emission material of the light emission material layer includes an organic light emitting diode material.

8. The semiconductor circuit of claim 6, further comprising:
a thin film transistor material layer adjacent to the sensor material layer;
a metal layer above the thin film transistor material layer;
the transparent cathode material layer above the metal layer;
the light emission material layer above the transparent cathode material layer; and
the transparent anode material layer above the light emission material layer; wherein,
the metal layer for providing a gate for a thin film transistor of the thin film transistor layer; and
the metal layer for shielding the sensor material layer from the light emitted by the light emission material layer.

9. The semiconductor circuit of claim 6, wherein the sensor material of the sensor material layer includes an organic light emitting diode material.

10. The semiconductor circuit of claim 9, wherein an organic light emitting diode of the sensor material layer is reverse biased during operation.

11. A semiconductor circuit for an emissive pixel comprising:
a substrate;
a first metal layer adjacent to a second metal layer, the first and the second metal layer above the substrate;
a thin film transistor material layer adjacent to a sensor material layer, the thin film transistor material layer above the first metal layer and the sensor material layer above the second metal layer;
a shield material layer above the thin film transistor material layer and the sensor material layer;
a transparent cathode material layer above the shield material layer;
a light emission material layer above the transparent cathode material layer; and
a transparent anode material layer above the light emission material layer; wherein
the shield material layer includes a cavity above the sensor material layer;
the shield material layer shields the thin film transistor material layer from the light emitted by the light emission material layer; and
the cavity in the shield material layer optically connects the light emission material layer with the sensor material layer.

12. The semiconductor circuit of claim 11, wherein the light emitted by the light emission material layer passes through the transparent anode material layer and the transparent cathode material layer.

13. The semiconductor circuit of claim 11, wherein the light emission material of the light emission material layer includes an organic light emitting diode material.

14. The semiconductor circuit of claim 11, wherein the first metal layer for providing a gate for a thin film transistor of the thin film transistor material layer.

15. The semiconductor circuit of claim 11, wherein the second metal layer for controlling the conductivity of the sensor material layer.

16. The semiconductor circuit of claim 11, wherein the sensor material of the sensor material layer includes an organic light emitting diode material.

17. The semiconductor circuit of claim 16, wherein an organic light emitting diode of the sensor material layer is reverse biased during operation.

18. A semiconductor circuit for an emissive pixel comprising:
a substrate;
a sensor material layer above the substrate;
an opaque cathode material layer above the sensor material layer;
a light emission material layer above the sensor material layer; and
a transparent anode material layer above the light emission material layer; wherein
the opaque cathode material layer including a cavity for forming an optical path between the light emission material layer and the sensor material layer.

19. The semiconductor circuit of claim 18, wherein the light emission material of the light emission material layer includes an organic light emitting diode material.

20. The semiconductor circuit of claim 18, further comprising:
a metal layer between the sensor material layer and the opaque cathode material layer for controlling the conductivity of the sensor material layer.

21. The semiconductor circuit of claim 18, wherein the sensor material of the sensor material layer includes an organic light emitting diode material.

22. The semiconductor circuit of claim 21, wherein an organic light emitting diode of the sensor material layer is reverse biased during operation.
